(19) United States
(12) Patent Application Publication
(10) Pub. No.: US 2009/0322350 A1
(43) Pub. Date: Dec. 31, 2009

(54) PRINTED CIRCUIT ASSEMBLY AND METHOD FOR MEASURING CHARACTERISTIC IMPEDANCE

(76) Inventors: Kemal Aygun, Chandler, AZ (US); Jaemin Shin, Phoenix, AZ (US)

Correspondence Address: INTEL CORPORATION;c/o CPA Global, P.O. BOX 52050, MINNEAPOLIS, MN, 55402, US

(21) Appl. No.: 12/165,327

(22) Filed: Jun. 30, 2008

(51) Int. Cl. G01R 27/04

(52) U.S. Cl. 324/642

(57) ABSTRACT

A printed circuit assembly is provided. The printed circuit assembly includes a plurality of signal layers and a plurality of test structures disposed within the plurality of signal layers, wherein each of the plurality of test structures comprises one of a microstrip and a stripline and wherein each of the plurality of test structures is to measure a characteristic impedance of each of the plurality of signal layers.

### BACKGROUND

With recent advancements in the semiconductor manufacturing technology microelectronic components are becoming smaller and circuitry within such components is becoming increasingly dense. As the chip size continues to be reduced and signals are clocked at increased frequencies, high frequency signals being driven between chips through signal traces on a printed circuit assembly may be subject to detrimental impedance effects. It is desirable to accurately measure the characteristic impedance of the signal traces of the printed circuit assembly to achieve better impedance control of the printed circuit assembly.

Various techniques are employed to measure the characteristic impedance of the signal traces in a printed circuit assembly. For example, a time domain reflectometry technique is used to measure the impedance of a first layer having minimum impedance discontinuity in a printed circuit assembly. Further, this impedance measurement is assumed to account for any impedance of signal traces in other layers of the printed circuit assembly. However, this may result in an inaccurate measurement of the characteristic impedance due to measurement error caused by impedance discontinuities in the structure of the printed circuit assembly.

### BRIEF DESCRIPTION OF THE DRAWINGS

Features of embodiments of the claimed subject matter will become apparent as the following detailed description proceeds, and upon reference to the drawings, in which like numerals depict like parts, and in which:

FIG. 1 illustrates an embodiment of a printed circuit assembly;

FIG. 2 is a plan view of an exemplary layout of a printed circuit assembly;

FIG. 3 is a cross-sectional view of an exemplary printed circuit assembly having striplines as test structures for characteristic impedance measurement;

FIG. 4 is a cross-sectional view of another exemplary printed circuit assembly having microstrips as test structures for characteristic impedance measurement;

FIG. 5 illustrates a process for measuring the characteristic impedance of signal layers of the printed circuit assembly of FIG. 3; and

FIG. 6 illustrates an embodiment of a computer system.

Although the following Detailed Description will proceed with reference being made to illustrative embodiments of the claimed subject matter, many alternatives, modifications, and variations thereof will be apparent to those skilled in the art. Accordingly, it is intended that the claimed subject matter be viewed broadly, and be defined only as set forth in the accompanying claims.

### DETAILED DESCRIPTION

As discussed in detail below, the embodiments of the present invention function to provide a printed circuit assembly having test structures embedded within signal layers of the printed circuit assembly to accurately measure characteristic impedance of each signal layer of the printed circuit assembly.

References in the specification to “one embodiment”, “an embodiment”, “an exemplary embodiment”, indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The embodiments of the present invention will be illustrated below in conjunction with exemplary printed circuit assemblies and signal layers. It should be understood, however, that the invention is not limited to use with any particular type of circuit assembly or signal layer, but is instead more generally applicable to a wide variety of impedance control applications. The term “circuit assembly” as used herein refers generally to any single layer or multi-layer device for supporting electronic circuitry, and is intended to include any printed circuit board, printed wiring board or other electronic hardware used for circuit or electronic component interconnection.

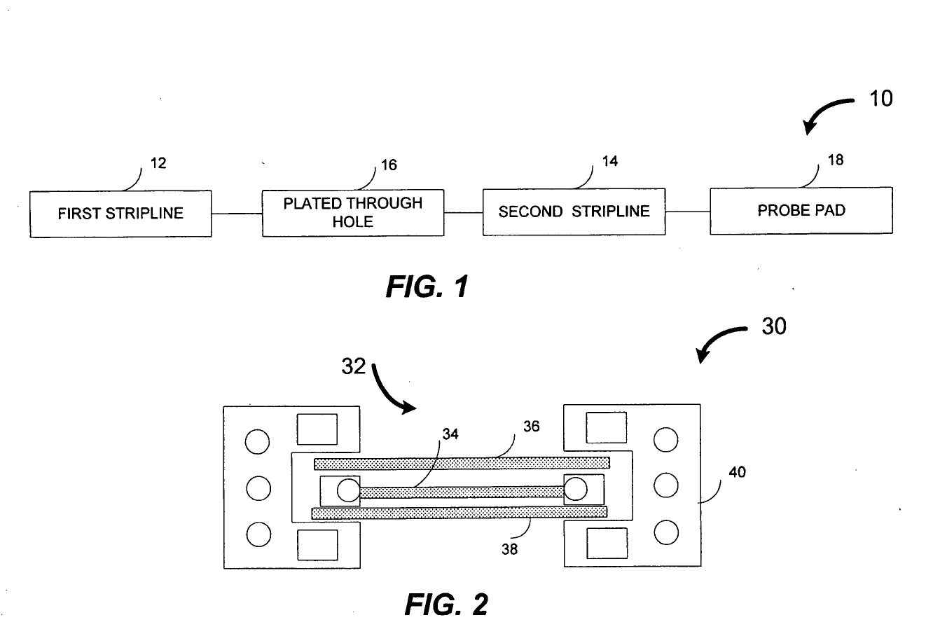

Referring first to FIG. 1, an exemplary printed circuit assembly 10 is illustrated. The printed circuit assembly 10 includes a plurality of signal layers or signal traces such as represented by reference numerals 12 and 14 for interconnection of electronic circuits on a substrate (not shown) of the printed circuit assembly 10. In this exemplary embodiment, the printed circuit assembly includes a first stripline 12 and a second stripline 14. Further, the second stripline 14 is electrically coupled to the first stripline 12 through a plated through hole (PTH) via 16. In this exemplary embodiment, a width of the first stripline 12 is about 60 micrometers and a width of the second stripline 14 is about 40 micrometers. In addition, the printed circuit assembly 10 includes a probe pad 16 for measuring the characteristic impedance of the first stripline 12 and the second stripline 14 in the printed circuit assembly 10.

The illustrated structure of the printed circuited assembly 10 having the first stripline 12, the second stripline 14 and the plated through hole 16 results in impedance discontinuities in the structure. As a result, the measured characteristic impedance of this structure of the printed circuit assembly 10 may deviate from desired characteristic impedance. In one exemplary embodiment, the measured characteristic impedance of the printed circuit assembly 10 is about 53.02 ohms as compared to a desired characteristic impedance of about 50 ohms.

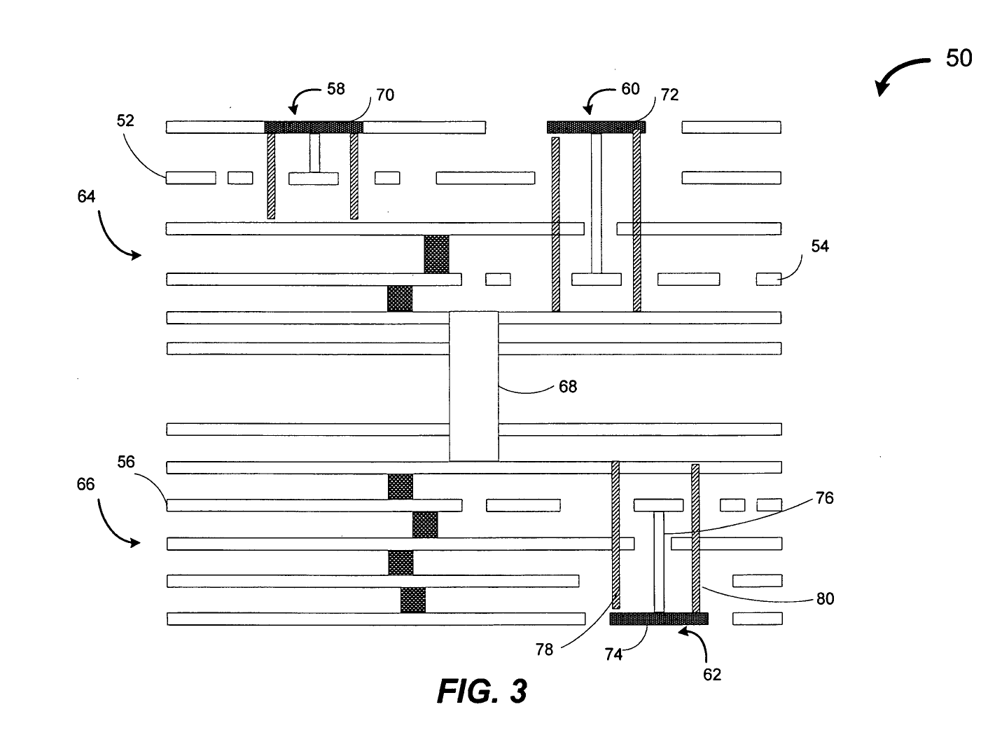

In this exemplary embodiment, the printed circuit assembly includes a test structure (not shown) in each of the signal layers such as in the first stripline 12 and the second stripline 14 to measure the characteristic impedance of each of the signal layers 12 and 14 and reduce the error due to the impedance discontinuities in the structure. In one embodiment, the test structure includes a microstrip. In another embodiment, the test structure includes a stripline. The details of the test structure will be described below with reference to FIGS. 2 and 3.

FIG. 2 is a plan view of an exemplary layout 30 of a printed circuit assembly 32. In this exemplary embodiment, the printed circuit assembly 34 includes signal layers such as traces represented by reference numerals 34, 36 and 38. In one exemplary embodiment, the signal layers include striplines. In this exemplary embodiment, the trace 34 represents the trace to be investigated for characteristic impedance. In this exemplary embodiment, addition, the printed circuit assembly 32 includes a test structure (not shown) embedded in the printed circuit assembly 32 to measure the characteristic impedance of the signal layer 34. In one embodiment, the test structure includes a stripline. In an alternate embodiment, the test structure 32 includes a microstrip. The printed circuit assembly 34 further includes a probe pad 40 coupled to the test structure for measuring the characteristic impedance of the signal layer 34.

As will be appreciated by one skilled in the art the printed circuit assembly 32 may include a plurality of signal layers. In certain embodiments, a test structure may be disposed in each of the plurality of signal layers of the printed circuit assembly 32 for accurately measuring the characteristic impedance of each of the signal layers. In one exemplary embodiment, the test structure may be disposed at a pre-determined location of a signal trace within each signal layer of the printed circuit assembly 32.

FIG. 3 is a cross-sectional view of an exemplary printed circuit assembly 50 having test structures such as stripline of FIG. 2. In the illustrated embodiment, the printed circuit assembly 50 includes a plurality of signal layers such as represented by reference numerals 52, 54 and 56. Further, the printed circuit assembly 50 includes a plurality of test structures such as represented by reference numerals 58, 60 and 62 disposed within the plurality of signal layers 52, 54 and 56. In certain embodiments, the printed circuit assembly 50 includes test structures in each signal layer where the signals are routed in the printed circuit assembly.

In this exemplary embodiment, each of the test structures 58, 60 and 62 includes a stripline. In an alternate embodiment, each of the test structures 58, 60 and 62 includes a microstrip. In the illustrated embodiment, the printed circuit assembly 50 includes a top portion 64 and a bottom portion 66. The bottom portion 66 is electrically coupled to the top portion 64 through a plated through hole 68. As illustrated, the top portion 64 includes the test structures 58 and 60 for measuring the characteristic impedance of the signal layers 52 and 54 of the top portion 64. Further, the bottom portion 66 includes the test structure 62 for measuring the characteristic impedance of the signal layer 56 of the bottom portion 66. However, a greater or a lesser number of test structures may be disposed within the top portion 64 and the bottom portion 66.

In the illustrated embodiment, each of the striplines 58, 60 and 62 include a probe pad such as represented by reference numerals 70, 72 and 74 to measure the characteristic impedance of the respective signal layers 52, 54 and 56. Each of the striplines 58, 60 and 62 includes a signal via 76 positioned between two parallel ground vias represented by reference numerals 78 and 80. Further, the probe pad such as 74 is coupled to the signal via 76 and to the ground vias 78 and 80. A time domain reflectometry (TDR) system (not shown) is coupled to each of the probe pads 70, 72 and 74. The time domain reflectometry system is to apply a fast rise time pulse to each of the plurality of test structures 58, 60 and 62 and to measure a voltage of a corresponding reflection wave from each of the plurality of test structures 58, 60 and 62 to measure the characteristic impedance of each of the signal layers 52, 54 and 56.

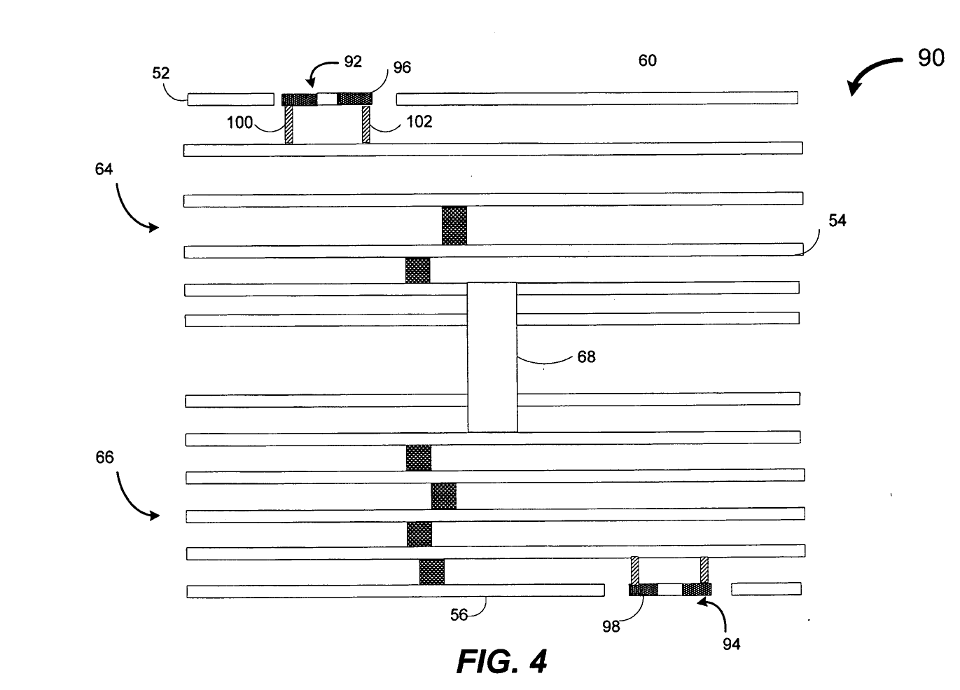

In the illustrated embodiment, the printed circuit assembly 50 includes striplines as the test structures 58, 60 and 62. However, in certain other implementations, microstrips may be employed as test structures 58, 60 and 62. One exemplary configuration of the printed circuit assembly with microstrips as test structures is described below with reference to FIG. 4.

In certain embodiments, the test structures may be embedded within the plurality of signal layers 52 and 56 for a set of printed circuit assemblies selected for characteristic impedance measurement. In one embodiment, the printed circuit assembly 50 includes a multi-layered circuit assembly having a plurality of signal layers within each layer of the multi-layered circuit assembly, and wherein the test structure is disposed in each of the plurality of signal layers of each layer of the multi-layered circuit assembly.

FIG. 4 is a cross-sectional view of another exemplary printed circuit assembly 90 having microstrips as test structures. As with the embodiment of FIG. 3, the printed circuit assembly 90 includes a plurality of signal layers such as represented by reference numerals 52 and 56. Further, the printed circuit assembly 90 includes a plurality of test structures such as represented by reference numerals 92 and 94 disposed within the signal layers 52 and 56. In this embodiment, each of the test structures 92 and 94 includes a microstrip.

As illustrated, the top portion 64 includes the test structure 92 for measuring the characteristic impedance of the signal layer 52 of the top portion 64. Further, the bottom portion 66 includes the test structure 94 for measuring the characteristic impedance of the signal layer 56 of bottom portion 66. However, a greater or a lesser number of test structures may be disposed within the top portion 64 and the bottom portion 66.

In the illustrated embodiment, each of the microstrips 92 and 94 include a probe pad such as represented by reference numerals 96 and 98 to measure the characteristic impedance of the respective signal layers 52 and 56. Further, the probe pad such as 96 is connected to the microstrip 92 and to ground vias 100 and 102. A time domain reflectometry (TDR) system (not shown) is coupled to each of the probe pads 96 and 98. The time domain reflectometry system is to apply a fast rise time pulse to each of the microstrips 92 and 94 and to measure a voltage of a corresponding reflection wave from each of the microstrips 92 and 94 to measure the characteristic impedance of each of the signal layers 52 and 56.

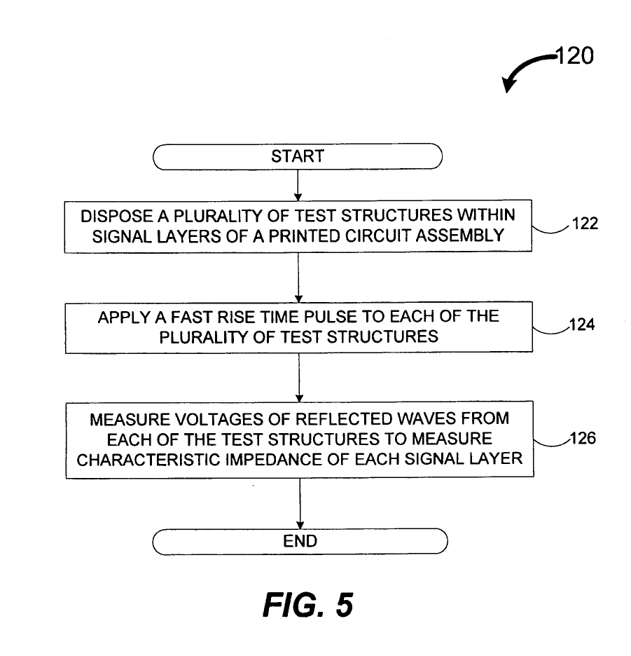

FIG. 5 illustrates a process 120 for measuring the characteristic impedance of signal layers 52, 54 and 56 of the printed circuit assembly 50 of FIG. 3. At block 122, a plurality of test structures are disposed within a plurality of signal layers of the printed circuit assembly. In one exemplary embodiment, a test structure is disposed in each of the signal layers of the printed circuit assembly. In one embodiment, each of the plurality of test structures includes a stripline. In an alternate embodiment, each of the plurality of test structures includes a microstrip. In certain embodiments, the plurality of test structures are disposed at pre-determined locations of signal traces within the printed circuit assembly.

At block 124, a fast rise time pulse is applied to each of the plurality of test structures of the printed circuit assembly. In one embodiment, a time domain reflectometry system is employed to apply fast rise time pulse to each of the plurality of test structures. Further, at block 126, voltages of reflected waves from each of the plurality of test structures is measured to measure the characteristic impedance of each of the plurality of signal layers of the printed circuit assembly. In this exemplary embodiment, a probe pad is coupled to each of the plurality of test structures to measure the voltages of the reflected waves from each of the plurality of test structures and to measure the characteristic impedance of each of the signal layers of the printed circuit assembly.

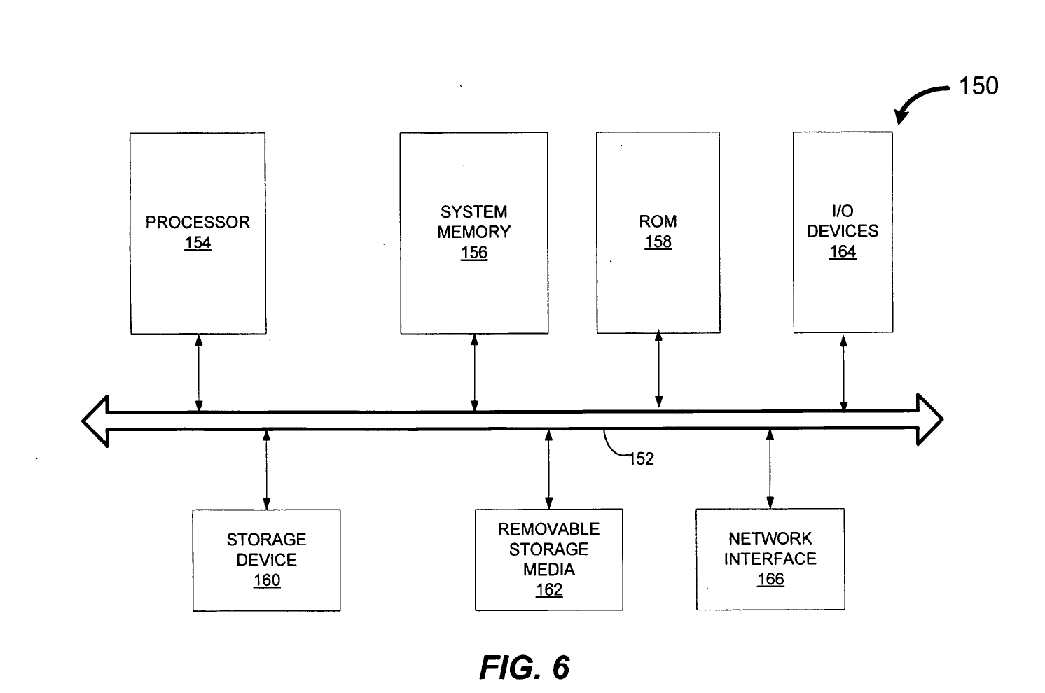

The printed circuit assembly described above may be disposed in a computer system, a wireless communicator and a hand-held device. FIG. 6 illustrates an embodiment of a computer system 150. The computer system 150 includes a bus 152 to which the various components are coupled. In certain embodiments, the bus 152 includes a collection of a plurality of buses such as a system bus, a Peripheral Component Interface (PCI) bus, a Small Computer System Interface (SCSI) bus, etc. Representation of these buses as a single bus 152 is provided for ease of illustration, and it should be understood that the system 150 is not so limited. Those of ordinary skill in the art will appreciate that the computer system 150 may have any suitable bus architecture and may include any number of combination of buses.

A processor 154 is coupled to the bus 152. The processor 154 may include any suitable processing device or system, including a microprocessor (e.g., a single core or a multi-core processor), a network processor, an application specific integrated circuit (ASIC), or a field programmable gate array (FPGA), or any similar device. It should be noted that although FIG. 6 shows a single processor 154, the computer system 150 may include two or more processors.

The computer system 150 further includes system memory 156 coupled to the bus 152. The system memory 156 may include any suitable type and number of memories, such as static random access memory (SRAM), dynamic random access memory (DRAM), synchronous dynamic random access memory (SDRAM), or double data rate DRAM (DDRDRAM). During operation of the computer system 150, an operating system and other applications may be resident in the system memory 156.

The computer system 150 may further include a read-only memory (ROM) 158 coupled to the bus 152. The ROM 158 may store instructions for the processor 154. The computer system 150 may also include a storage device (or devices) 160 coupled to the bus 152. The storage device 160 includes any suitable non-volatile memory, such as, for example, a hard disk drive. The operating system and other programs may be stored in the storage device 160. Further, a device 162 for accessing removable storage media (e.g., a floppy disk drive or a CD ROM drive) may be coupled to the bus 152.

The computer system 150 may also include one or more Input/Output (I/O) devices 164 coupled to the bus 152. Common input devices include keyboards, pointing devices such as a mouse, as well as other data entry devices. Further, common output devices include video displays, printing devices, and audio output devices. It will be appreciated that these are but a few examples of the types of I/O devices that may be coupled to the computer system 150.

The computer system 150 may further comprise a network interface 166 coupled to the bus 152. The network interface 166 comprises any suitable hardware, software, or combination of hardware and software that is capable of coupling the system 150 with a network (e.g., a network interface card). The network interface 166 may establish a link with the network over any suitable medium (e.g., wireless, copper wire, fiber optic, or a combination thereof) supporting exchange of information via any suitable protocol such as TCP/IP (Transmission Control protocol/Internet Protocol), HTTP (Hyper-Text Transmission Protocol, as well as others.

It should be understood that the computer system 150 illustrated in FIG. 6 is intended to represent an embodiment of such a system and, further, that this system may include any additional components, which have been omitted for clarity and ease of understanding. By way of example, the system 150 may include a direct memory access (DMA) controller, a chip set associated with the processor 154, additional memory (e.g., cache memory) as well as additional signal lines and buses. Also, it should be understood that the computer system 150 may not include all the components shown in FIG. 6. The computer system 150 may comprise any type of computing device, such as a desktop computer, a laptop computer, a server, a hand-held computing device, a wireless communication device, an entertainment system etc.

In this embodiment, the computer system 150 may include the printed circuit assembly as described in the embodiments above. By way of example, the printed circuit assembly may include a plurality of test structures disposed within the plurality of signal layers of the printed circuit assembly. The test structures may include one of striplines and microstrips. The test structures may be embedded in each of the plurality of signal layers to accurately measure the characteristic impedance of each of the signal layers thereby reducing any measurement error due to impedance discontinuities in the printed circuit assembly.

Further, the characteristic impedance measured using the test structures may be utilized to adjust dimensions of signal traces of the printed circuit assembly to achieve a desired characteristic impedance of the signal traces. The impedance of each of the signal traces may be controlled by adjusting trace width, thickness of the trace, height of the circuit board and the dielectric constant of the board material of the printed circuit assembly. Thus, the characteristic measurement technique described above facilitates fabrication optimization of the printed circuit assembly to achieve a target impedance of the printed circuit assembly.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

1. A printed circuit assembly, comprising:
a plurality of signal layers;
a plurality of test structures disposed within the plurality of signal layers, wherein each of the plurality of test structures comprises one of a microstrip and a stripline and wherein each of the plurality of test structures is to measure a characteristic impedance of each of the plurality of signal layers.

2. The printed circuit assembly of claim 1, further comprising a probe pad coupled to each of the plurality of test structures and to a ground layer, wherein the probe pad is to measure the characteristic impedance of each of the plurality of signal layers.

3. The printed circuit assembly of claim 2, further comprising a time domain reflectometry system coupled to the probe pad, wherein the time domain reflectometry system is to apply a fast rise time pulse to each of the plurality of test structures and to measure a voltage of a corresponding reflection wave from each of the plurality of test structures to measure the characteristic impedance.

4. The printed circuit assembly of claim 1, wherein a width of the microstrip is about 20 microns to about 60 microns and a height of the microstrip is about 10 microns to about 20 microns.

5. The printed circuit assembly of claim 1, wherein a width of the stripline is about 20 microns to about 60 microns and a height of the stripline is about 10 microns to about 20 microns.

6. The printed circuit assembly of claim 1, wherein a test structure is disposed in each of the plurality of signal layers to measure the characteristic impedance of each of the plurality of signal layers.

7. The printed circuit assembly of claim 1, wherein the printed circuit assembly is a multi-layered circuit board having a plurality of signal layers within each layer of the multi-layered circuit board, and wherein the test structure is disposed in each of the plurality of signal layers of each layer of the multi-layered board.

8. The printed circuit assembly of claim 1, wherein each of the plurality of test structures is disposed at a pre-determined location of a signal trace of the printed circuit assembly.

9. A method of measuring characteristic impedance, comprising:
applying a fast rise time pulse to a plurality of test structures disposed within a plurality of signal layers of a printed circuit assembly; and
measuring voltages of reflection waves from each of the plurality of test structures to measure the characteristic impedance of the plurality of signal layers.

10. The method of claim 9, wherein each of the plurality of test structures comprise a microstrip.

11. The method of claim 9, wherein each of the plurality of test structures comprise a stripline.

12. A test assembly for a printed circuit assembly having a plurality of signal layers, comprising:
a test structure disposed in each of the plurality of signal layers;
a ground layer;
a probe pad coupled to the test structure and to the ground layer; and
a time domain reflectometry system coupled to the probe pad, wherein the time domain reflectometry system is to apply a fast rise time pulse to the test structure and to measure voltage of a corresponding reflection wave from the test structure to measure the characteristic impedance of each of the plurality of signal layers.

13. The test assembly of claim 12, wherein the test structure comprises a microstrip.

14. The test assembly of claim 13, wherein a width of the microstrip is about 20 microns to about 60 microns and a height of the microstrip is about 10 microns to about 20 microns.

15. The test assembly of claim 12, wherein the test structure comprises a stripline.

16. The test assembly of claim 15, wherein a width of the stripline is about 20 microns to about 60 microns and a height of the microstrip is about 10 microns to about 20 microns.

17. The test assembly of claim 12, wherein the printed circuit assembly is a multi-layered board having a plurality of signal layers within each layer of the multi-layered circuit board and wherein the test structure is disposed in each of the plurality of signal layers in each layer of the multi-layered circuit board.

18. The test assembly of claim 12, wherein the characteristic impedance measured from the test assembly is used to adjust the dimensions of signal traces of the circuit board to achieve a desired characteristic impedance of the signal traces.

19. The test assembly of claim 12, wherein the desired characteristic impedance is about 50 ohms.

20. The test assembly of claim 12, wherein the test structure for each of the plurality of signal layers reduces a measurement error due to impedance discontinuity between the plurality of signal layers.
